(19) United States
(12) Patent Application Publication
(10) Pub. No.: US 2019/0131484 A1
(43) Pub. Date: May 2, 2019

(54) Solar Cell and Cutting Method and Device thereof

(71) Applicant: MiaSole Equipment Integration (Fujian) Co., Ltd., Quanzhou, Fujian (CN)

(72) Inventors: Xiaoning Ru, Quanzhou,Fujian (CN); Minghao Qu, Quanzhou,Fujian (CN); WEI Long, Quanzhou,Fujian (CN); Qizheng Jiang, Quanzhou,Fujian (CN); Yi SHU, Quanzhou,Fujian (CN); Fan Chen, Quanzhou,Fujian (CN)

(73) Assignee: MiaSole Equipment Integration (Fujian) Co., Ltd., Quanzhou, Fujian (CN)

(21) Appl. No.: 16/097,232

(22) PCT Filed: Jul. 26, 2018
(86) PCT No.: PCT/CN2018/097287

§ 371 Date: Oct. 26, 2018

(30) Foreign Application Priority Data
Aug. 30, 2017 (CN) 201710765841.5

(51) Int. Cl. H01L 31/18; H01L 31/0445; H01L 21/78

(52) U.S. Cl. CPC H01L 31/18; H01L 21/78; H01L 31/0445

(57) ABSTRACT

This application provides a solar cell, a cutting method and a cutting device for the solar cell, the cutting method for the solar cell includes: cutting a continuous thin-film solar cell on a substrate into at least one intermediate transition cell with a preset size; carrying out integrated lamination on one of the intermediate transition cells, a packaging material and a metal wire to form a transition laminated cell; cutting the transition laminated cell into a plurality of single-piece cells, and cutting edge angles of the single-piece cells to form fillets.

This application is a National phase of International Patent Application No. PCT/CN2018/097287, filed on Jul. 26, 2018, which claims the priority of CN application No. 201710765841.5 filed on Aug. 30, 2017, the entire contents of all of which are incorporated herein by reference.

### TECHNICAL FIELD

This application relates to the technical field of solar cells and in particular relates to a solar cell and a cutting method and device thereof.

### DESCRIPTION OF RELATED ART

At present, an efficient thin-film solar cell such as a copper indium gallium diselenide thin-film solar cell or a gallium arsenide thin-film solar cell which produced on a large scale on the market is regarded as a second-generation solar cell capable of replacing a crystal silicon solar cell and has the advantages such as high photoelectric conversion efficiency, good stability and high anti-radiation ability. A thin-film solar cell based on a flexible substrate such as stainless steel is light in weight, windable, flexible in unfolding way and high in mass specific power so as to have a wide market application prospect and to be favored by people increasingly.

For a winding large-sized thin-film solar cell product, it is needed that a large-sized cell is cut into a specific size to meet the electric use demand of an output product, and a plurality of single-piece cells are integrated and packaged to form a final product required.

### SUMMARY

This application provides a cutting method for a solar cell, including the blocks of:

cutting a continuous thin-film solar cell on a substrate into at least one intermediate transition cells with a preset size;

carrying out integrated lamination on any one of the intermediate transition cells, a packaging material and a metal wire to form a transition laminated cell; and

cutting the transition laminated cell into a plurality of single-piece cells, and cutting edge angles of the single-piece cells to form fillets.

This application further provides a solar cell which comprises at least one fillet, and the fillets are cut by using any one of the cutting methods.

This application further provides an arc cutter for cutting the solar cell, which at least comprises an arc-shaped blade and a rectangular blade; the arc cutter is molded by combining the arc-shaped blade with the rectangular blade, or the arc cutter is integrally molded by the arc-shaped blades and the rectangular blades.

### BRIEF DESCRIPTION OF THE DRAWINGS

The specific embodiments of this application are further described in detail below in combination with the accompanying drawings.

FIG. 1 is a state diagram of bent angles generated on single-piece cells in the prior art.

FIG. 2 is a flow diagram of a cutting method of a solar cell provided by an embodiment of this application.

FIG. 3 is a flow diagram of another cutting method of a solar cell provided by an embodiment of this application.

FIG. 4 is a schematic diagram of the single-piece cells of which the edge angles are cut.

FIG. 5 is a schematic diagram of an arc cutter used in the cutting method for a solar cell provided by the embodiment of this application.

### DETAILED DESCRIPTION

The embodiments of this application are described in detail below, examples of the embodiments are shown in the accompanying drawings, wherein the symbols which are same or similar throughout represent for the same or similar elements or elements with same or similar functions. The embodiments described below by referring to the accompanying drawings are illustrative and are merely intended to explain this application, rather than to limit this application.

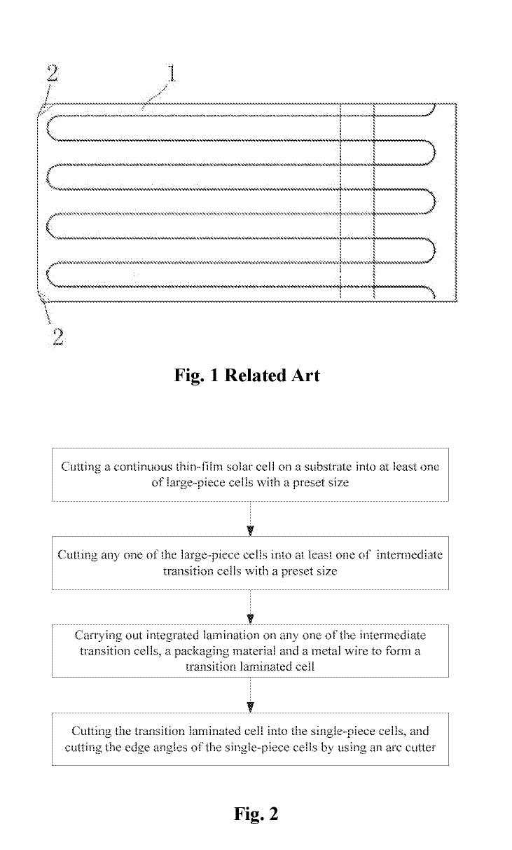

As shown in FIG. 1, the cells unavoidably generate the phenomenon of bent angles 2 under the influences of external forces such as driving, cutting, transportation and manipulator collection in a process that small-sized single-piece cells 1 are prepared and integrated to form a product; and when a plurality of single-piece cells 1 are connected in series, it is easy for the bent angles 2 of a former single-piece cell to directly conduct stainless steel of the next single-piece cell 1 after pricking insulating layers to result in a short circuit phenomenon of a thin-film solar cell module. Moreover, the bent angles 2 of the single-piece cells 1 prick a backing plate material to conduct aluminum layers serving as waterproof layers to result in other potential risks of module packaging short circuit such as short circuit inside the thin-film solar cell module, so that the preparation quality of the module is seriously affected.

According to the cutting method for a solar cell provided by this application, the edge angles of the single-piece cells are cut into the fillets in a reciprocated cutting way of the arc cutter, so that the problem that the edge angles upwarp to form the bent angles to damage insulating layers or waterproof layers of the adjacent single-piece cells to further result in short circuit inside or outside the cells in the prior art is avoided.

As shown in FIG. 2, the embodiment of this application provides a cutting method for a solar cell, including the blocks of:

a continuous thin-film solar cell on a substrate is cut into at least one immediate transition cell with a preset size, wherein the length of the immediate transition cell may ranges from 1500 to 1600 mm and the width of the immediate transition cell ranges from 40 mm to 45 mm; and in the embodiment, the immediate transition cell has the length of 1588 mm and the width of 43.75 mm; it should be explained that the size of “a continuous thin-film solar cell on a substrate” is not specifically limited in this embodiment, and the number of cutting times from “a continuous thin-film solar cell on a substrate” to “an intermediate transition cell” is not specifically limited in this embodiment;

carrying out integrated lamination on one of the intermediate transition cells, a packaging material and a metal wire to form a transition laminated cell; and

cutting the transition laminated cell into a plurality single-piece cells, and cutting edge angles of the single-piece cells to form fillets.

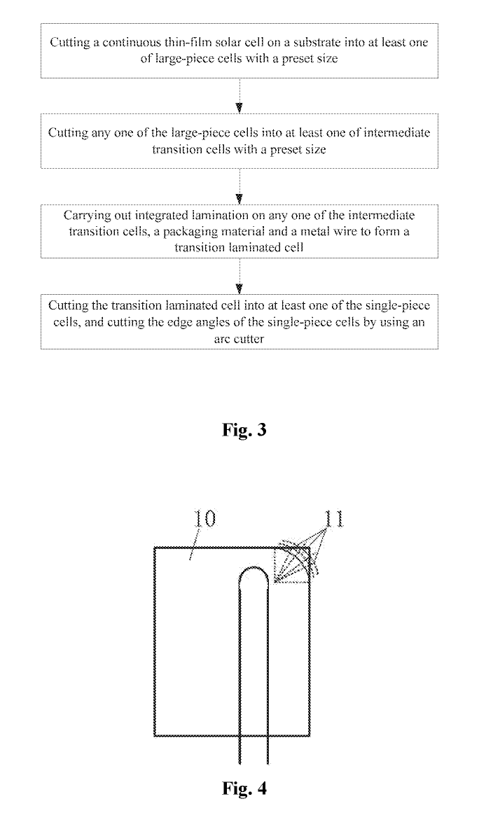

As shown in FIG. 3, the embodiment of this application provides another cutting method for a solar cell, including the blocks of:

a continuous thin-film solar cell on a substrate is cut into at least one large-piece cell with a preset size, wherein the preset size may be determined according to an actual production demand, in the embodiment, the large-piece cell has a length of 1588 mm and a width of 1000 mm.

The large-piece cell is cut into an immediate transition cell with a preset size, wherein the immediate transition cell may have a length within the range of 1500-1600 mm and a width within the range of 40-45 mm; and in the embodiment, the immediate transition cell has the length of 1588 mm and the width of 43.75 mm.

The intermediate transition cell, a packaging material and a metal wire are subjected to integrated lamination to form a transition laminated cell.

The transition laminated cell is cut into single-piece cells 1, the edge angles of the single-piece cells 1 are cut by using arc cutter, the cutters for cutting the edge angles of the single-piece cells 1 are arc-shaped to ensure that the edge angles of the single-piece cells 1 form fillets 11 after being cut, as shown in FIG. 4, so that the problem that the edge angles upwarp to form the bent angles to damage insulating layers or waterproof layers of the adjacent single-piece cells 1 to further result in short circuit inside or outside the cells in the prior art is avoided.

The single-piece cells 1 may ranges from 300 mm to 320 mm, and the width of the single-piece cells ranges from 40 mm to 45 mm, and in the embodiment, the length of the single-piece cells is 310 mm and the width of the single-piece cells is 43.75 mm.

In another cutting method for a solar cell provided by the embodiment of this application, a continuous thin-film solar cell on a substrate is first cut into at least one large-piece cell with a preset size, then the large-piece cell is cut into an intermediate transition cell with a preset size , the intermediate transition cell is integratedly laminated with a packaging material and a metal wire to form a transition laminated cell; and the transition laminated cell is then cut into single-piece cells. That is, in this embodiment, the size relationship between the surface area of “the large-piece cell”, “the intermediate transition cell” and “the single-piece cell” obtained by the cutting is: “the large-piece cell”>“the intermediate transition cell”>“the single-piece cell”.

It should be explained that the step that the transition laminated cell is cut into the single-piece cells 1 may specifically include: the transition laminated cell is cut into the single-piece cells 1 via cooperation of rectangular blades 20 and arc cutter, so that the efficiency of cutting the transition laminated cell may be increased. Further, the transition laminated cell may be cut into the single-piece cells 1 by using the rectangular blades via cooperation of the rectangular blades and arc-shaped blades, and meanwhile, the arc-shaped blades complete the cutting of one edge angle of each of the single-piece cells obtained by cutting to obtain single-piece cells with each having one fillet, so that the efficiency of cutting the transition laminated cell is increased.

Further, the step that the edge angles of the single-piece cells are cut by using the arc cutter specifically includes:

The arc cutter are mounted on a cell cutting device.

The arc cutter are controlled to move in a direction perpendicular to a driving direction of the single-piece cells 1, wherein the cutting depths of the arc cutter on the single-piece cells 1 are required to be adjusted in a direction perpendicular to a cutting direction before cutting, so that the radians of the cut fillets 11 are controlled, not only may the cells not be scratched by the fillets 11, but also a cut material may be reduced as much as possible, and material wastes are reduced.

It should be explained that the “cutting depth” in the “cutting depth on the single-piece cells 1” may be explained as follows: a geometric shape for defining an edge angle of a to-be-cut single-piece cell is composed of two edges and a common end point of the two edges, and the “cutting depth” herein refers to the degree that the cutting positions of the arc cutter are far away from the common end point. If the distance from the cutting positions of the arc cutter to the common end point is longer, the “cutting depth” is larger, and the radians of the fillets obtained after cutting are large; and if the distance from the cutting positions of the arc cutter to the common end point is shorter, the “cutting depth” is smaller, and the radians of the fillets obtained after cutting are small.

One edge angle on an edge of the single-piece cell 1 is cut.

A turntable for holding the single-piece cells 1 is controlled to rotate 90°.

The other edge angle on the edge is cut.

Specifically, the arc cutter may return to initial positions after cutting one edge angle of one single-piece cell 1; after the turntable for holding the single-piece cells 1 rotates 90°, the other edge angle on the single-piece cell 1 is cut by using the arc cut; the arc cutter return to the initial positions again after the two edge angles of the single-piece cell 1 are cut down, and the edge angles of the next single-piece cell 1 are cut again by using the arc cutter when the next single-piece cell 1 is driven to a cutting position; therefore, the cutting of two edge angles of one single-piece cell 1 is realized by the reciprocating movement of the arc cutter, and meanwhile, the continuous cutting of a plurality of single-piece cells 1 is realized by the continuous reciprocating movement of the arc cutter, so that the cutting efficiency is effectively increased. The arc cutter may realize automatic cutting by virtue of a pneumatic control unit; of course, the arc cutter may also realize cutting in a manual way under the condition that the amount of the single-piece cells 1 is smaller, and the cutting way is not limited by the embodiment.

It should be explained that the position of the cell cutting device is fixed during cutting operation, and the cutting of the edge angles of the single-piece cells is realized by the cooperated movement of the turntable and a conveying mechanism; in the other embodiment, when the single-piece cells move to the cutting position along with the conveying mechanism, arc cutter move downwards to cut one edge angle on the edge of the single-piece cell, the arc cutter return to the initial position after the cutting is completed; at the moment, the cell cutting device horizontally moves to a position of the other edge angle on the edge along the edge, meanwhile, the arc cutter rotate 90°, so that arcs of the arc cutter are protruded towards a direction deviated from the single-piece cells, and the arc cutter are driven to move downwards to cut the other edge angle; the arc cutter return after the cutting is completed, meanwhile, the cell cutting device horizontally moves to the initial position along a direction opposite to the edge; the cut single-piece cells are conveyed to a cutting region by the conveying mechanism, and meanwhile, the next to-be-cut single-piece cell is conveyed to the cutting region, so that the continuous cutting of the single-piece cells is realized.

The arc cutter may be controlled to move with a step length when moving in a direction perpendicular to a driving direction of the single-piece cells 1, so that the consistency of cutting sizes of the single-piece cells 1 may be guaranteed, the cutting depth may be prevented from being over-large or over-small; meanwhile, a certain time interval may exist during the conveyance of every two adjacent single-piece cells 1, and it is convenient to control the arc cutter in a continuous cutting state.

Further, the arc cutter provided by this application may be composed of one, two or four blades. When the arc cutter includes two arc-shaped blades, namely a first arc-shaped blade and a second arc-shaped blade, the first arc-shaped blade and the second arc-shaped blade are arranged along the edge of the to-be-cut cell, or the first arc-shaped blade and the second arc-shaped blade are arranged along a diagonal of the to-be-cut cell. The distance between the two arc-shaped blades may be set according to the size (length or width) of the to-be-cut cell, and meanwhile, the cutting of the two edge angles of the to-be-cut single-piece cell is completed; when the arc cutter includes four arc-shaped blades, the distance among the four arc-shaped blades may be set according to the size (length and width) of the to-be-cut single-piece cell; and meanwhile, the cutting of the four edge angles of the to-be-cut single-piece cell is completed, so that the cutting efficiency is further increased; and meanwhile, the relative positions of the plurality of arc-shaped blades are fixed, so that the consistency of radians of the four fillets obtained after cutting is further improved, and the finished product rate of the cells is increased.

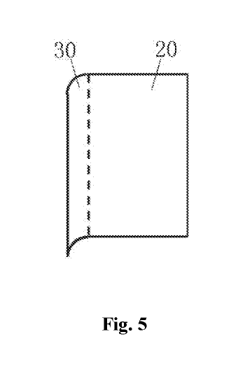

As shown in FIG. 5, the arc cutter may be an integrated flake cutter with one end being arc-shaped or a combination of arc-shaped blades 30 and rectangular blades 20; in the embodiment, the arc cutter are mounted on the cell cutting device in a way that the arc-shaped blades 30 are combined with the rectangular blades 20, in order to increase the use function of the arc cutter, and the rectangular blades 20 may be dismounted to be independently used when being required to be used.

Further, the arc cutter provided by this application may be composed of one arc-shaped blade and one rectangular blade; the arc cutter may also be composed of two arc-shaped blades and one rectangular blade, here, the rectangular blade is arranged between the two arc-shaped blades; and the arc cutter may also be composed of four arc-shaped blades and two rectangular blades, here, the two rectangular blades are arranged between every two arc-shaped blades, and are oppositely arranged; Thus, the cutting of the four edge angles may be completed simultaneously, so that the consistency of radians of the four fillets obtained after cutting is improved; and the sizes of the single-piece cells may be further adjusted by the rectangular blades, so that the consistency of the sizes of the single-piece cells in batch products is improved, and the finished product rate of the cells is further increased.

Further, after the arc cutter is mounted on the cell cutting device, the cutting method further includes:

The cutting position of the arc cutter is adjusted by moving the arc cutters along a diagonal where to-be-cut edge angles of the single-piece cells are located to control the sizes of fillets formed after the edge angles are cut, so that the control on the radians of the fillets formed after cutting may be realized by changing the depths of the arc-shaped blades 30 relative to the single-piece cells 1 in a direction perpendicular to a cutting direction.

Specifically, the radian of the arc-shaped blades 30 may be π/2, and the maximum radian of the fillets 11 do not exceed π/2.

It should be explained that as shown in FIG. 3, the single-piece cells 1 have certain flexibility, if the depth that the arc cutter are in contact with the edge angles of the single-piece cells 1 in the direction perpendicular to the cutting direction is over-small, the single-piece cells 1 are easily departed from cutting edges of the cutters due to deformation in a cutting process to result in cutting irregularity, thereby causing the quality problem of the single-piece cells 1; therefore, it should be ensured that the cutters have certain cutting depths in the direction perpendicular to the cutting direction in an actual cutting process, so as to set the minimum radian of the fillets 11; in the embodiment, the minimum radian of the fillets 11 are π/96, and therefore, the radian of the fillets 11 may be set between π/96 and π/2 according to actual demands.

Further, after the transition laminated cell is cut into the single-piece cells 1 and the edge angles of the single-piece cells 1 are cut by using the arc cutter, the cutting method may further include:

The forming quality of the single-piece cells 1 is detected, the single-piece cells 1 are collected in grades, so that appearance or performance problems existing in the cut single-piece cells 1 are found, and timely separation or correction management is carried out.

According to the cutting method for a solar cell provided by this application, the edge angles of the single-piece cells are cut into the fillets in a reciprocated cutting way of the arc cutter, so that the problem that the edge angles upwarp to form the bent angles to damage insulating layers or waterproof layers of the adjacent single-piece cells to further result in short circuit inside or outside the cells in the prior art is avoided.

The embodiments shown according to the accompanying drawings are used for describing the structure, features and effects of this application in detail and are merely embodiments of this application, however, the implementation scope of this application is not limited by the accompanying drawings, and equivalent embodiments varied and modified to form equivalent variations according to the concept of this application should fall into the scope of this application when not departing from the spirit of the description and the accompanying drawings.

1. A cutting method for a solar cell, comprising:
cutting a continuous thin-film solar cell on a substrate into at least one intermediate transition cell with a preset size;
carrying out integrated lamination on one of the intermediate transition cells, a packaging material and a metal wire to form a transition laminated cell; and
cutting the transition laminated cell into a plurality of single-piece cells, and cutting edge angles of the single-piece cells to form fillets.

2. The cutting method for the solar cell according to claim 1, wherein cutting a continuous thin-film solar cell on a substrate into at least one intermediate transition cell with a preset size comprises:
cutting a continuous thin-film solar cell on a substrate into at least one large-piece cell with a preset size; and
cutting one of the large-piece cells into at least one intermediate transition cell with a preset size.

3. The cutting method for the solar cell according to claim 1, wherein cutting edge angles of the single-piece cells to form fillets comprises:
cutting the edge angles of the single-piece cell by using an arc cutter to form fillets.

4. The cutting method for the solar cell according to claim 3, wherein cutting edge angles of the single-piece cell by using an arc cutter comprises:
mounting an arc cutter on a cell cutting device;
controlling the arc cutter to move in a direction perpendicular to a driving direction of the single-piece cell;
cutting one edge angle on an edge of the single-piece cell;
controlling a turntable for holding the single-piece cell to rotate 90°; and
cutting the other edge angle on the edge.

5. The cutting method for the solar cell according to claim 3, wherein cutting edge angles of the single-piece cell by using an arc cutter comprises:
mounting an arc cutter on a cell cutting device;
controlling the arc cutter to move in a direction perpendicular to a driving direction of the single-piece cell, and at the same time, cutting two or four edge angles of the single-piece cell.

6. The cutting method for the solar cell according to claim 4, wherein controlling the arc cutter to move in a direction perpendicular to a driving direction of the single-piece cell comprises:
controlling the arc cutter to move with a set step length.

7. The cutting method for the solar cell according to claim 5, wherein after the arc cutter are mounted on the cell cutting device, the cutting method further comprises:
adjusting a cutting position of the arc cutter by moving the arc cutter along a diagonal where the edge angles of the single-piece cell are located, so as to control the size of the fillets formed after the edge angles are cut.

8. The cutting method for the solar cell according to claim 3, wherein the arc cutter is molded by combining an arc-shaped blade with a rectangular blade, or the arc cutter is integrally molded by an arc-shaped blade and a rectangular blade.

9. The cutting method for the solar cell according to claim 4, wherein the arc cutter is molded by combining an arc-shaped blade with a rectangular blade, or the arc cutter is integrally molded by an arc-shaped blade and a rectangular blade.

10. The cutting method for the solar cell according to claim 5, wherein the arc cutter is molded by combining an arc-shaped blade with a rectangular blade. or the arc cutter is integrally molded by an arc-shaped blade and a rectangular blade.

11. The cutting method for the solar cell according to claim 1, wherein the length of the single-piece cells ranges from 300 mm to 320 mm, the width of the single-piece cells ranges from 40 mm to 45 mm, the length of the immediate transition cell ranges from 1500 to 1600 mm, and the width of the immediate transition cell ranges from 40 mm to 45 min.

12. The cutting method for the solar cell according to claim 1, wherein after the transition laminated cell is cut into the single-piece cells and the edge angles of the single-piece cells are cut by the arc cutter, the cutting method further comprises:
detecting the forming quality of the single-piece cells, and carrying out graded collection.

13. The cutting method for the solar cell according to claim 1, wherein cutting the transition laminated cell into a plurality of single-piece cells comprises:
cutting the transition laminated cell into a plurality of single-piece cells by cooperation of a rectangular blade and an arc-shaped blade.

14. A solar cell, comprising:
at least one fillet which is cut by using a cutting method, wherein the cutting method comprises:
cutting a continuous thin-film solar cell on a substrate into at least one intermediate transition cell with a preset size;
carrying out integrated lamination on any one of the intermediate transition cells, a packaging material and a metal wire to form a transition laminated cell; and
cutting the transition laminated cell into a plurality of single-piece cells, and cutting edge angles of the single-piece cells to form fillets.

15. The solar cell according to claim 14, wherein the radian of the fillets of the fillet solar cell ranges from π/96 to π/2.

16. An arc cutter for cutting the solar cell, wherein the arc cutter comprises at least one arc-shaped blades and at least one rectangular blades;
the arc cutter is molded by combining the arc-shaped blade with the rectangular blade, or the arc cutter is integrally molded by the arc-shaped blade and the rectangular blade.

17. The arc cutter for cutting the solar cell according to claim 16, wherein the arc cutter at least comprises a first arc-shaped blade and a second arc-shaped blade, the first arc-shaped blade and the second arc-shaped blade are arranged along an edge of a to-be-cut cell; or the first arc-shaped blade and the second arc-shaped blade are arranged along a diagonal of the to-be-cut cell.

18. The arc cutter for cutting the solar cell according to claim 17, wherein the radian of the first arc-shaped blade is π/2, or the radian of the second arc-shaped blade is π/2.
